(19) United States
(12) Patent Application Publication
(10) Pub. No.: US 2021/0312098 A1
(43) Pub. Date: Oct. 7, 2021

(54) ENHANCED SELECTION FILTERING WITHIN COMPUTER-AIDED DESIGN

(71) Applicant: Applied Software Technology, Inc., Atlanta, GA (US)

(72) Inventors: Christopher Jones, Atlanta, GA (US); James Simpson, Atlanta, GA (US); Kerry Poe, Atlanta, GA (US)

(21) Appl. No.: 17/218,747

(22) Filed: Mar. 31, 2021

Related U.S. Application Data
(60) Provisional application No. 63/003,683, filed on Apr. 1, 2020.

(51) Int. Cl. G06F 30/12; G06F 30/13; G06F 30/20

(52) U.S. Cl. CPC G06F 30/12; G06F 30/20; G06F 30/13

(57) ABSTRACT

Examples can include a system for filtering selections made within a computer-aided design (“CAD”) application. A plugin can generate a filter designer window that is displayed on a graphical user interface (“GUI”). The plugin can receive criteria for a first filter based on an edit tab that allows the user to select a parameter, operator, and operand. The user can categorize and edit the filters and apply them to the selection. The plugin can loop through elements within a selection box and automatically deselect elements that do not meet the criteria of the first filter. Remaining selected elements can be visually indicated as specified by the first filter.

### CROSS-REFERENCE TO RELATED APPLICATION

This application claims the benefit of and priority to U.S. Provisional Application Ser. No. 63/003,683, filed on Apr. 1, 2020, titled “Enhanced Selection Filtering Within REVIT,” the contents of which are hereby incorporated herein by reference in their entirety.

### BACKGROUND

Computer-aided design (“CAD”) software allows users to design structures for construction, among other things. One type of CAD software is Building Information Modeling (“BIM”) software, which allows users to elaborately design three-dimensional structures. AUTODESK REVIT is one type of BIM software that can be used to design complex buildings all the way down to components and assemblies for use in a project. For example, a user can model an entire plumbing or electrical installation within a building.

REVIT allows users to add elements, such as electrical assemblies, to a design layout that is displayed in a graphical user interface (“GUI”). Often, a user will want to select particular elements within a complex design layout. Doing so can be difficult. For example, the user may need to draw a box around many elements and then deselect unwanted elements one by one. It may be impossible for a user to physically notice and deselect the unwanted elements.

REVIT provides some standard filtering for selections, but it is limited. If a user wants to select particular element types, such as conduit, the user must navigate a complex list of filter rules that may or may not include the elements that the user wants to select. Conditions within the REVIT selection filter is limited to three attributes and only the AND operator between them. Users cannot easily program their own filters. Additionally, even the available filters within REVIT require far too many clicks, which add up over time.

Nevertheless, users are limited to using REVIT in many cases because of REVIT's widespread success.

For at least these reasons, a need exists for flexible selection filters for use with REVIT for granularly selecting components within a REVIT GUI.

### SUMMARY

The examples described herein specifically address technical problems and limitations of REVIT and similar BIM software. The examples include a computing device, such as a personal computer, tablet, or laptop, that executes a computer-aided design application such as REVIT. The application can include an application programming interface (“API”) that interacts with a plugin that supplies additional functionality for auto-filtering. The plugin can include a selection filter engine that executes on the computing device.

A plugin can generate a filter designer window that is displayed on a GUI. The plugin can receive criteria for a first filter based on an edit tab that allows the user to select a parameter, operator, and operand. The user can categorize and edit the filters and apply them to the selection. The plugin can loop through elements within a selection box and automatically deselect elements that do not meet the criteria of the first filter. Remaining selected elements can be visually indicated as specified by the first filter. Multiple selected filters can be applied such that multiple sets of criteria are checked and the elements not meeting the criteria are deselected.

The plugin can include a filtering engine for creating the filter designer window and executing saved filters as part of selections. The filter designer window can include tabs for filter categories, an editor, and additional filtration options. The editor tab can allow a user to add any number of conditions (also referred to as criteria). The conditions can include a parameter. The parameter can be any attribute of an element within REVIT, such as hole diameter, radius, and length. The attributes can be retrieved by the plugin by making API calls to REVIT to determine all the different attributes for elements within the GUI (i.e., within the layout), in an example.

The editor tab can also allow the user to select an operator and an operand. The operator can be any function, such as less than, greater than, minimum, maximum, and equal to. The operator can be a value or an element selected within the GUI. For example, the operand can be “longer than” and the operator can be a selected part. Multiple criteria can be included for a single filter. They can be linked together with complex conditional operators, such as AND/OR, NOT, and others. An options tab can include visualization selections for showing which elements are selected by the filter and which elements the filter omits. This can ensure that the user understands how their selection has been modified by the filters.

In one example, a separate selection icon is displayed on the GUI for use with the filtering engine. The plugin can generate the button for display in the CAD application, such as within the REVIT GUI. When the user makes a selection, such as by drawing a box on the GUI, the elements within the selected area are filtered using the custom filter(s) selected by the user. The filer can automatically deselect items that do not meet the filter criteria. The filter can also highlight the remaining selected items. Deselected items can be colored differently and omitted from the selection.

The method can be performed by a system in an example. The method can also be implemented based on code stored on a non-transitory, computer-readable medium, which is read and executed by a process of a computing device.

Although REVIT is referred to as an example, the systems and methods can operate with other CAD and BIM applications. These systems and methods can reduce the operational time required by a user, greatly enhance the user experience, and prevent the user from accidentally selecting items that they do not intend to select within the GUI.

### BRIEF DESCRIPTION OF THE DRAWINGS

FIG. 1A is an example flow chart showing example stages for custom filtration in a computer-aided design application, such as REVIT.

FIG. 1B is an example sequence diagram showing example stages for custom filtration in a computer-aided design application, such as REVIT.

FIG. 2A is an illustration of an example GUI screen.

FIG. 2B is an illustration that continues the example GUI screen of FIG. 2A.

FIG. 3A is an example illustration of a filter designer window.

FIG. 3B is an example illustration of a filter designer window.

FIG. 3C is an example illustration of a filter designer window.

FIG. 3D is an example illustration of a filter designer window.

FIG. 4 is an example illustration of system components.

### DESCRIPTION OF THE EXAMPLES

Reference will now be made in detail to the present examples, including examples illustrated in the accompanying drawings. Wherever possible, the same reference numbers will be used throughout the drawings to refer to the same or like parts.

In some examples, users can customize workflows by creating parameter-based selection filters. Users can save these “filters” in order to reuse them in conjunction with REVIT commands. The filters can determine which selected parts to keep in within a selection, such that a user can draw a selection box around multiple parts without also selecting parts that are not meant to be included. For example, an assembly may have particular part types but be connected to other pieces that are not included as part of the assembly. Custom selection filters can allow the user to easily select particular assemblies without including other captured parts. Likewise, if a user would like to select all parts with a particular characteristic within an area, such as all ducts longer than one foot, a custom selection filter can allow the user to do so. Additionally, the system can allow the user to convert the selection filters into “view filters,” which may be applied to any views within the model. This can allow a user to eliminate noise and focus on particular details within the GUI that they may want to view. The selection filter is intended to be a general-use tool within a CAD application that will also allow users to feed the more specific selection into other commands.

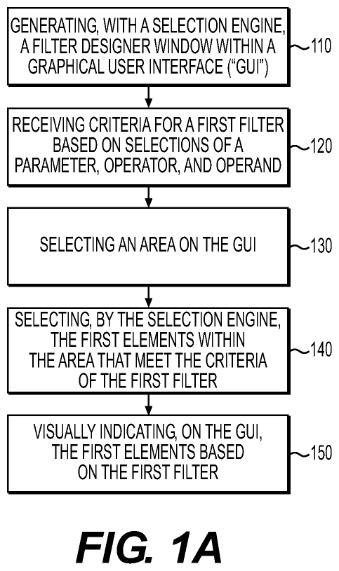

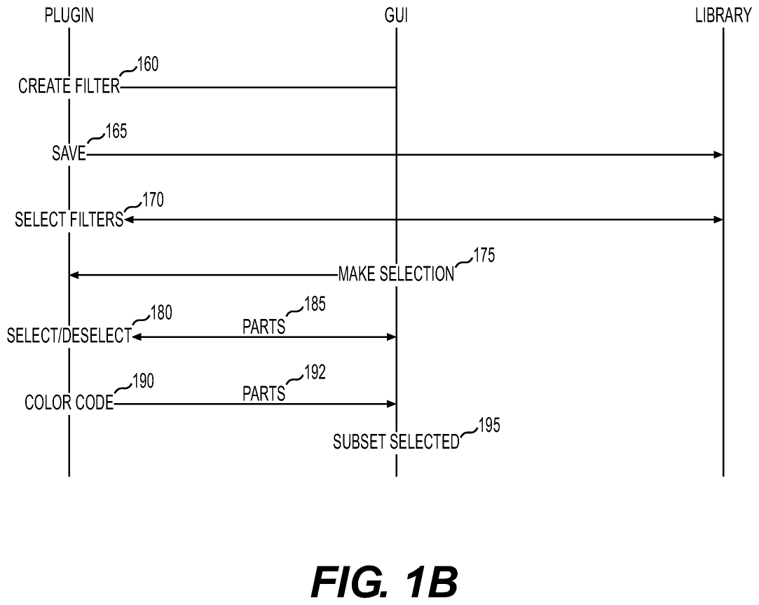

FIG. 1A is an example illustration of method stages performed in an example. At stage 110, the plugin can generate a filter designer window within a GUI of REVIT. The plugin can run as part of REVIT, providing additional functionality in an example. The functionality can include a selection engine, which can be responsible for generating the filter designer window, saving filters, and applying filters to selections made within the GUI. The selection engine can be part of the CAD application in an example. Alternatively, the selection engine can be supplied by a plugin that operates with the CAD application.

The filter designer window can include features for creating, saving, and selecting multiple selection filters. For example, the filter designer window can include multiple tabs for finding, editing, and creating filters. A filter can have user-defined criteria. The user can save the selection filter in a library. Then the user can enable one or more of the saved selection filters to apply to future selections on the GUI that the user makes with a selection tool.

The selection engine of the GUI can generate the filter designer window sand some features of the selection tool. For example, the plugin can interact with the CAD application, such as REVIT, through API calls. This can cause the GUI of the CAD application to display custom buttons and menu items. For example, a special selection tool can be activated with one such button. Additionally, the plugin can cause the GUI to display buttons or menu items for viewing the filter designer window for purposes of creating or enabling particular selection filters.

In one example, the user can create a new filter or search for an existing filter that is already saved in a filter library. Either can involve the entry of criteria for a filter into the filter designer window at stage 120. The criteria can include one or more conditions that specify which types of parts to select or deselect when the user draws a selection box on the screen. Each condition can include a parameter, operator, and operand. The parameter can be any attribute of an element (e.g., part) within the GUI. The plugin can retrieve a list of all elements and all attributes of those elements, in an example, based on API interactions with the CAD application. The attributes can then populate a dropdown that the user can select for a criterion (i.e., condition). For example, parameters can include diameter, length, width, part types, and others.

The user can select one or more parameters that the filter will use. For purposes of filter search, these selected parameters can be compared against existing stored filters in a library. The user can select an existing filter, create a new filter, or modify and save an existing filter as a new filter.

In one example, part types are specified on a separate tab of the filter designer, such as a categories tab. The categories tab can include a hierarchical tree of all the part types present within the GUI. The plugin can make API calls to REVIT to retrieve the present part types, in an example. Those can be displayed for selection in a nested tree, such that an assembly is displayed with an arrow for possible expansion. The user can then select the types of parts that the filter should select or de-select. For example, the user may want to select ducts and pipes with a diameter greater than two inches. A filter can be created with duct and pipe part types as parameters.

The user can similarly select an operator and operand for the parameter. For example, the operator can be “greater than” and the operand can be two inches. The example filter for ducts and pipes with a diameter greater than two inches can include a diameter attribute parameter with an operator of greater than with an operator of two inches. The parameter for duct and pipe part types can be either part of the diameter parameter or separate. For example, Boolean operators for duct and pipe part types can be included.

The user can assign one or more filters to selections either before or during selection. For example, a hotkey or GUI button can activate the selection filter. In one example, the selection filter can be applied to an already selected set of elements, whereas in another example the selection filter can be activated for a future selection.

At stage 130, the user can select an area on the GUI, such as by drawing a box. Then at stage 140, for a selected area on the GUI, the selection engine can determine first elements within the area that meet the criteria of the first filter. To do this, the selection engine can receive the list of elements selected in the area. Then, looping through the elements, the selection engine can compare each to the criteria of the first filter. For each condition of the first filter, the selection engine can request the parameter value of the element being compared. This can include making an API call to REVIT (or other CAD applications). Alternatively, the selection engine can retrieve the value from the element, such as when that value has already been supplied by REVIT. When the condition is a comparison to another element, the plugin can retrieve the relevant value of that comparison element with an API call to REVIT.

Then the selection engine can compare the value against the operand for the condition, using the operator. This comparison can determine whether the individual element is included in a set of selected elements (called the first elements).

If the conditions are met, the element is included in the set of selected elements (the first elements). Otherwise, the selection engine can deselect the element in an example. For the purposes of this disclosure, deselection can include simply not selecting those elements in the first place based on applying the selection filter as part of the selection process. In this way, deselection can be synonymous with a lack of selection. For example, if the element does not meet the criteria of the filter, it may never be included in the list of selected elements in an example. Alternatively, the deselection can include removing the element from the set of selected elements. This can occur in scenarios where the filter is applied by the selection engine after the set of elements has already been selected. For example, the user might click a button to apply the filter to a selection that they have already made on the GUI. Alternatively, the selection filter of some examples receives the selected set of elements as part of selection and removes from the set those elements that do not meet the filter criteria. To deselect the element, the selection engine can make an API call to REVIT for deselection, identifying the element.

The selection engine can continue this process through all of the elements in the selected area, applying all of the criteria of the selected filter(s). This can include looping through a list of elements that fall within the selection box or that have already been selected and are part of the set of selected elements.

At stage 150, the GUI can visually indicate the first elements (i.e., the selected elements that meet the selection criteria). The visual indication can be based on the filters applied to the selection. For example, the filter designer window can include options for visualization. These visualization options can be assigned to a filter. Options can include color and transparency. The options can be applied differently to elements that meet the filter and those that do not, in an example. For example, de-selected elements can be shown with a transparency whereas the first elements can be shown with a selection color. Selected elements similarly can be colored differently than a normal selection in the CAD application otherwise would be, to help visually remind the user that a filter was applied to the selection.

Designing and applying selection filters in this way can allow a user to more effectively use the CAD application to focus on specific tasks related to specific elements and configurations of those elements. The user can easily determine that the desired elements remain selected while unwanted elements are deselected.

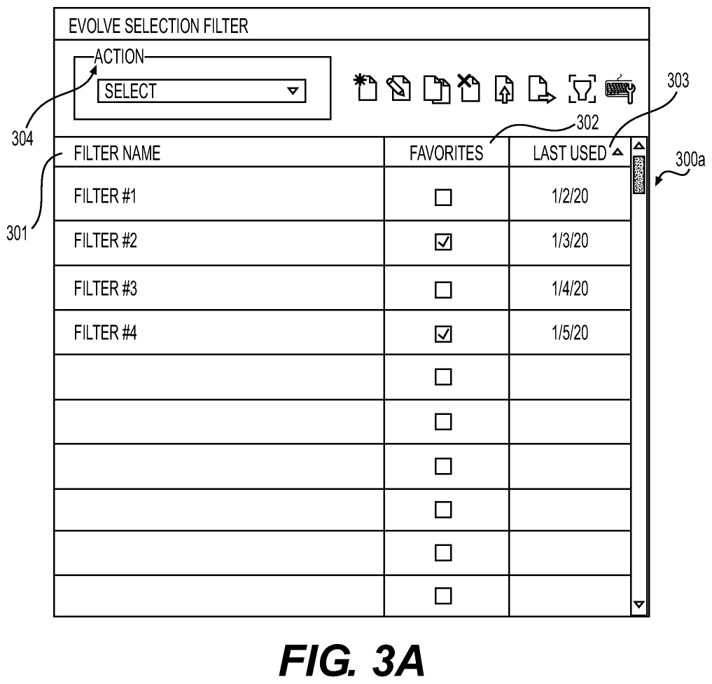

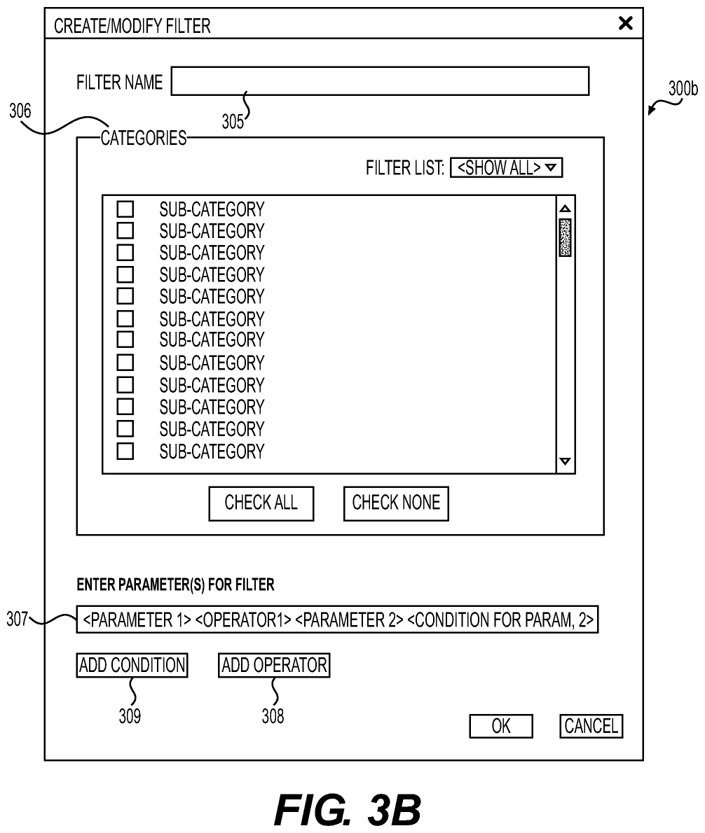

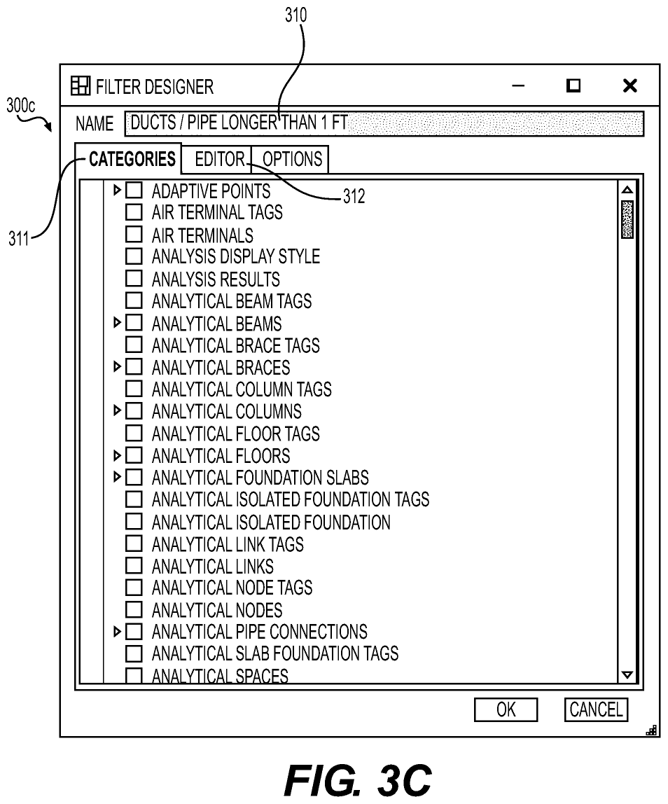

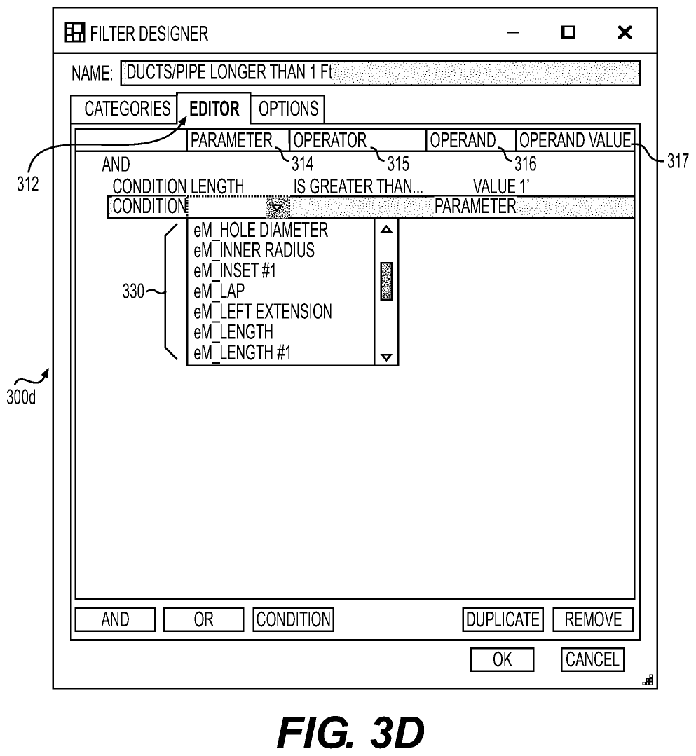

FIG. 1B is an example sequence diagram for providing selection filters in a CAD application through use of a plugin. The plugin can provide the selection engine discussed above, in an example. At stage 160, the plugin can provide functionality for creating a filter. For example, the plugin can operate with an API of the CAD application to provide menu options or buttons for filter creation and selection. When the user selects such an option, a window can be presented for designing the filter, such as described later for FIG. 3B. The user can make selections within the designer window for creating the filter. For example, the user can select a parameter, such as a part type or attribute of the part type. The user can then create a condition for that parameter, such as a comparison to a value or to another part type.

At stage 165, the plugin can save the new filter. The filter can be saved in one or more categories that apply to a part type or assembly type (which can include multiple part types) implicated by the filter. This can allow the user to easily find relevant filters without having to constantly recreate them.

The plugin can save the filter in a library of filters. The library can exist on the user device that is running the CAD application or on a server, such as in the cloud. The library can store information about the filters, such as which categories the filters are in, names for the filters, and all of the criteria for the filters. The plugin can retrieve these existing filters and display them for selection in a window of the GUI, in an example.

At stage 170, the user can select one or more filters to apply to a selection. This can stage can be performed before or after the selection to which the filters will apply, depending on the example. For example, the user can select two filters that will apply to future selections, in an example. In another example, the user can first make a selection and then, while the elements are selected, choose an option to apply one or more filters to those selected elements.

Ats stage 175, the user can make a selection within the GUI. The CAD application can provide a layout window that includes elements used in building projects, such as electrical and plumbing assemblies. The user can make a selection using a selection tool, such as a lasso tool or a selection box. The regular selection tool of the CAD application can be used in one example, with the selected elements being then determined by interaction with the selection engine of the plugin. In another example, the plugin provides a filtered selection tool, such that the user can easily switch between filtered and non-filtered selections.

When the user makes a selection at stage 175, the selected elements can be identified to the plugin at stage 185. At stage 180, the plugin can then apply the active selection filter(s) to the elements (e.g., parts). This can determine which of the elements to ultimately include in the set of selected elements. The filters can specify which elements to select or deselect. For example, a filter for ductwork can cause all non-duct elements to be deselected (e.g., ignored) and all duct-type elements to be selected.

The plugin can deselect elements in one example by making API calls to the CAD application. For example, the plugin can send an element identifier and invoke a function that causes deselection of that element. Alternatively, the plugin can identify which elements are selected to the CAD application. This can include making an API call with one or more element identifiers and invoking a function to select those elements.

At stage 190, the selected duct elements can be highlighted differently than the non-selected elements that were originally within the bounds of the selection box. The non-selected elements can be partially transparent, or ghosted, in an example. The highlighting can occur as part of stage 180, in an example. To cause each element to highlight according to application of the filters, the plugin can make an API call to the CAD application at stage 192. The API call can include identifying the element with an element identifier and invoking a function to change the visualization of that element.

At stage 195, the CAD application can then display the selected subset of elements (i.e., the first elements). These can be displayed according to any visualizations applied in stages 190 and 192.

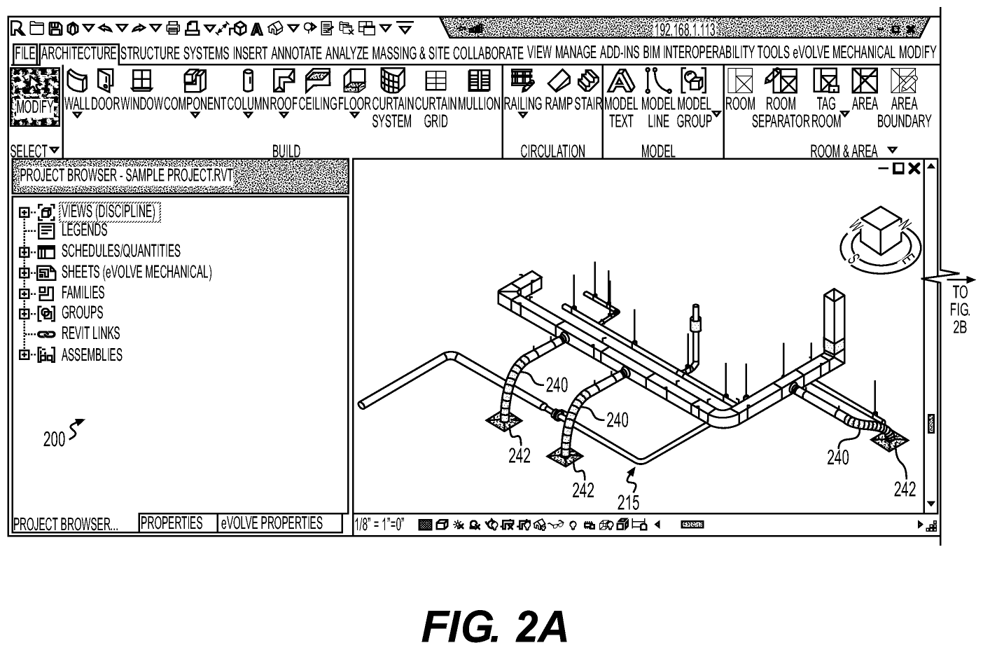

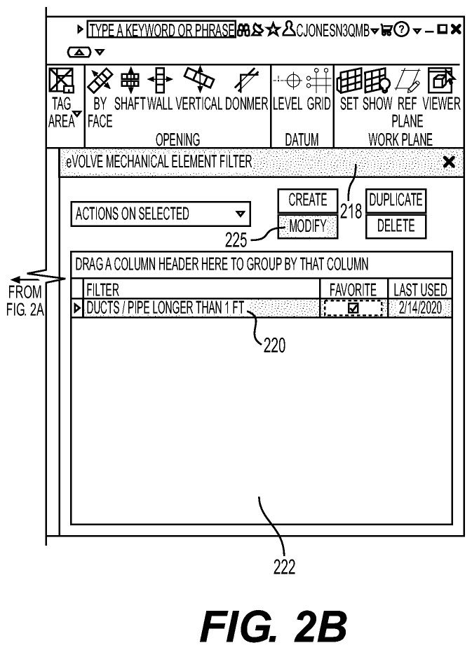

FIGS. 2A and 2B together provide an example illustration of the GUI 210 that can be used with examples described herein. The GUI 210 of both FIGS. 2A and 2B can be presented on a single screen, in an example, but is spread across two pages for explanatory purposes.

The GUI 210 can display one or more elements 215 together in a design layout. In this example, HVAC and plumbing elements are displayed together in the design layout. The user can select an area within the GUI 210 by drawing a box, such as by clicking and dragging. For example, the user can select some or all of the elements 215 by drawing a selection box in the design layout.

Next to the design layout, as shown in FIG. 2B, a selection filter window 218 can allow the user to activate one or more filters for use with selections. The filter window 218 in this example includes a length filter 220 that the user created. Filter pane 222 can show which filters will apply to selected elements. The user can select one or more filters that they have already created. They can also select a modify button 225 to change the filters.

Active or prospective filters can also display their respective selection criteria in the filter pane 222 of the selection window 218, in an example. In this example, the length filter 220 displays as requiring ducts or pipe longer than one foot. This means that the filter can cause selections to ultimately select elements that are ducts or pipes and that have a length of longer than one foot while removing or otherwise omitting non-qualifying elements from the selection. The user can toggle these filters on and off in an example, allowing for easily changing the combination of which filters will apply to a selection.

With this filter 220 active, the user can select the elements 215 of the design layout. Doing so can cause elements 240 to be selected since they are duct type and longer than one foot. Conversely, elements 242 will be deselected (not ultimately selected) based on not being longer than one foot. Even though elements 242 can be duct type elements, their length can disqualify them from selection. However, if a second filter for duct fittings is also active, then elements 242 can remain selected if they meet the criteria of the second filter.

The selection filter window 218 can also include options for when to apply the active filters. In this example, a dropdown box with the option “Actions on Selected” can indicate that the filters will apply to any selection. Other options can also be available. For example, “Actions on Command” can rely on a hotkey or button for applying the filters to a selection. Another option can be “Actions on View,” which can apply the filters to all elements that are within view in the design layout. This can be useful, for example, when a user wants the filter to remain in place regardless of selection, such as to view particular element types more clearly within the larger project. Other selectable actions are described with regard to FIG. 3A.

FIG. 3A is an example illustration of a filter designer window 300a. The filter designer window 300a can list several filters 301 that have already been created. The filters can be retrieved by the plugin from a library in an example. The user can add these filters to a favorites tab in one example. The user can also select which filters to apply to a selection. Alternatively, the user can assign the filters to a hotkey, so that the user can make a selection then use the hotkey to run the filter. The filter designer window 300a can allow the user to select favorites 302, which can then display on the filter pane 222 of FIG. 2B in an example. The filter designer window 300a can also indicate when each filter was last used 303.

An action dropdown 304 can allow the user to select how the filters will be applied. A “Filter Selection” action can cause the plugin to prefilter when selecting. When elements are selected, this action can add elements that meet the filter's criteria to the current selection. When no elements are selected, this action can select only elements meeting the filter's criteria.

A “select” action can select elements. When elements are selected this action can further filter the current selection based on the filters, leaving only elements meeting the filter's constraints selected. When no elements are selected, the plugin can select all elements in the current view if the elements meet the filter criteria.

A “halftone” action can apply halftone to elements meeting the filter criteria. When elements are selected, the plugin can apply a halftone to the currently selected elements if the elements meet the filter's criteria. When no elements are selected, the plugin can apply a halftone to all of the elements in the current view if the elements meet the filter criteria.

A “transparent” action can apply a 100% transparency to elements that meet or do not meet filter criteria, depending on user preference. When elements are selected, the transparency applies to the selected elements meeting filter criteria. Otherwise, the action can apply to the entire view.

An “isolate” action can isolate elements meeting the filter criteria and can hide all elements that do not. This can apply to a selection or the entire view. Similarly, a “hide” action can do the inverse. “Temporary isolate” and “temporary hide” actions can do the same thing except can utilize a temporary view to do so. The temporary view can open separately from the design layout view of the GUI.

Finally, a “restore” action can remove the various halftone, transparency, isolate, and hide actions that may have been applied by the user.

FIG. 3B is an example illustration of a filter designer window 300b. In this example, the user can create or modify a filter. Various categories of elements can be shown. The elements can be those that exist within the GUI 210, within REVIT generally, or within a specific list utilized by the plugin, in an example. The user can select which of the elements the filter should apply to, in an example.

The filter designer window 300b can also allow the user to enter parameters, operators, and conditions for the filter.

This example includes a categories pane 306 where the user can select which types of elements the filter applies to. In a categories pane 306, element types to which the filter can apply are organized according to category, then sub-category. The user can select the types of elements to which the filter applies by marking boxes in the tree structure. For example, plumbing can be a category, with pipes and fittings as two sub-categories, and with different types of pipes as a sub-category of the pipes sub-category. With this sort of tree structure, the user can easily create filters that are as broad or narrow as needed. Alternatively, the user can select certain types of elements to blacklist or whitelist.

To specify how to further filter those selected element types, the user can edit parameters and operators to create filtration criteria in box 307. This can specify the criteria for filtering of the chosen element types, in an example. Various conditions and operators can be added using buttons 308, 309. Numerous conditions can be created for a single filter. For example, width can be greater than one inch and length can be less than one foot, for one filter. The filter can be applied to any number of element types.

The user can also type a name of the filter in the name filed 305. Then the user can select “OK” to create the new filter, which can be displayed according to its name or criteria.

FIG. 3C is another example illustration of a filter designer window 300c. This example includes a categories tab 311 where the user can select which types of elements the filter applies to. In this example, the arrows next to categories indicate that the respective category can expand to reveal selectable sub-categories.

In this example, the name field 310 states that the filter is called “Ducts/Pipe Longer than 1 Ft.” To create this filter, the user can select duct and pipe categories from within the categories tab 311.

Then the user can add the “longer than one foot” criteria using the editor tab 312.

FIG. 3D is an example illustration of a filter designer window 300d having an editor tab 312. The editor tab 312 can allow the user to very conveniently add conditions that make up the selection criteria. The conditions can include a selected a parameter, operator, and operand. In this example, the first condition includes a length parameter. The operand is “greater than” and the operand is the value 1.

The various conditions can display in a table having columns for parameter 214, operator 315, operand 316, and operand value 317. The first condition, specifying length greater than a value of 1 is included as a first entry.

In the example of FIG. 3D, the user is in process of adding a second condition below the first condition. The parameter is being selected from a dropdown list that includes a plurality of parameters 330. The dropdown list can be populated by the plugin. The plugin can make an API call to REVIT to retrieve all parameters, in an example. Alternatively, the plugin can retrieve only those parameters that are part of elements of the GUI, narrowing the universe of selection. The user can select the parameter of the second condition, then add an operator and operand.

In one example, the parameters 330 available for selection are dictated by which categories are selected in the categories tab in FIG. 3C. Different element types can have different attributes. The attributes can serve as selectable parameters 330. In one example, when multiple different element types are selected in the categories tab, the attributes in common between the different element types are presented as available parameters 330 for selection.

The user can also add an operator between conditions. For example, in FIG. 3D the two conditions utilize an AND operator, meaning both must be met. However, complex conditions are available. The user could instead insert an AND/OR condition or parenthesis around multiple conditions, one of which must be met, with an AND for another condition outside the parenthesis.

In one example, the parameter of one element may be set with respect to another element for filter selection. For example, the parameter may include length of conduit is greater than the max length or greater than the length of another part, such as a strut.

Under the options tab, a user can define the actions that the filter should perform such as select, isolate, show, hide, make half tone, make transparent. Also, the options tab can enable the inclusion of part insulation.

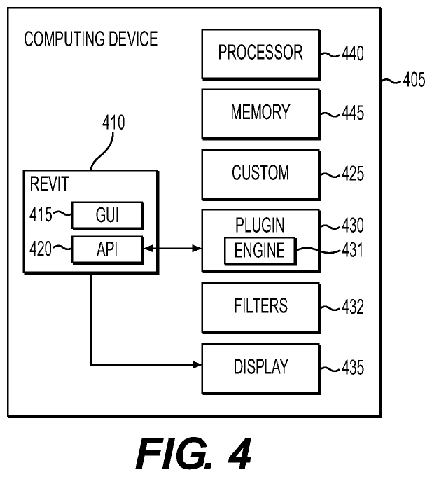

FIG. 4 is an illustration of example system components. The computing device 405 can be any processor-based device, such as a personal computer, workstation, server, phone, or laptop. The computing device 405 can include a processor 440 and memory 445. The processor 440 can be one or more physical processors that are local to the computing device 405 or virtual computer processing units that are accessed remotely. The memory 445 can be non-transitory and can store instructions for execution by the processor 445.

The processor 440 can run a computer-aided design application, such as REVIT 410. Any CAD application can operate with the examples herein, but REVIT 140 is used as an example here. REVIT 410 can include a GUI 415 that executes to display a design layout and workspace for a user. The design layout can include parts and assemblies, all of which can be considered elements to which filters apply. The GUI can be generated on a display 435. The display 435 can be any type of screen and can be integrated into the computing device 405 or separate from the computing device 405.

REVIT 410 can utilize the plugin 430 to add functionality related to filtering searches. The plugin 430 can make API 420 calls to REVIT to integrate itself within the workflow. This can include altering the GUI 415 and providing additional functional items, such as menu items and buttons, for use with the auto-dimensioning. The plugin 430 can receive information, such as elements within a search area, from REVIT 410, and send back information such as elements that should be de-selected (e.g., for not meeting filter criteria). The plugin 430 can also create a filter designer window in an example.

In one example, the plugin 430 creates and accesses filters 432 to determine what criteria to apply to elements within a selected area. The filters 432 can be keyed to part or assembly identifiers (e.g., specific element types) in an example. A database, either local or remote from the computing device 405, can store the filters 432 and be accessed by the plugin 430.

In one example, a selection engine 431 can perform the various stages performed by the plugin. The selection engine 431 can interpret the filter 432 conditions, compare against selected elements, and modify the selection by de-selecting some elements and highlighting elements that meet the filter 432 conditions.

Although a plugin is described in some examples, the computer-aided application, such as REVIT, can alternatively build the described functionality directly into the application. The examples can still apply to that scenario as well. Additionally, though REVIT is referred to for convenience, the examples can also function with any other computer-aided design application.

Other examples of the invention will be apparent to those skilled in the art from consideration of the specification and practice of the examples disclosed herein. Though some of the described methods have been presented as a series of steps, it should be appreciated that one or more steps can occur simultaneously, in an overlapping fashion, or in a different order. The order of steps presented are only illustrative of the possibilities and those steps can be executed or performed in any suitable fashion. Moreover, the various features of the examples described here are not mutually exclusive. Rather any feature of any example described here can be incorporated into any other suitable example. It is intended that the specification and examples be considered as exemplary only, with a true scope and spirit of the invention being indicated by the following claims.

What is claimed is:

1. A method for filtering selections in a computer-aided design application, comprising:
generating, with a selection engine, a filter designer window within a graphical user interface (“GUI”);
receiving criteria for a first filter to apply to an element type based on selections of a parameter, operator, and operand;
for a selected area on the GUI, determining first elements within the area that meet the element type and criteria of the first filter; and
visually indicating, on the GUI, the first elements based on the first filter.

2. The method of claim 1, wherein determining first elements within the area includes:
for a set of elements within the area criteria, automatically de-selecting elements that do not meet the criteria by making an application programming interface (“API”) call from the selection engine to the GUI.

3. The method of claim 1, further comprising creating a set of different filters using the filter designer window, wherein the first filter is within the set.

4. The method of claim 1, further comprising causing second elements that do not meet the criteria of the first filter to hide or display as transparent.

5. The method of claim 1, wherein the parameter is chosen from a list of parameters populated based on element types within the GUI, wherein common attributes of the element types are used to populate the parameter list.

6. The method of claim 1, wherein the operator and operand form a comparison against an element that exists within the GUI, and wherein the criteria include an and/or condition.

7. The method of claim 1, wherein the first filter includes a color coding and transparency that are used for visually indicating the first elements.

8. A non-transitory, computer-readable medium containing instructions for filtering selections made as part of computer-aided design, wherein a processor executes the instructions to perform stages comprising:
generating, with a selection engine, a filter designer window within a graphical user interface (“GUI”);
receiving criteria for a first filter to apply to an element type based on selections of a parameter, operator, and operand;
for a selected area on the GUI, determining first elements within the area that meet the element type and criteria of the first filter; and
visually indicating, on the GUI, the first elements based on the first filter.

9. The non-transitory, computer-readable medium of claim 8, wherein determining first elements within the area includes:
for a set of elements within the area criteria, automatically de-selecting elements that do not meet the criteria by making an application programming interface (“API”) call from the selection engine to the GUI.

10. The non-transitory, computer-readable medium of claim 8, the stages further comprising creating a set of different filters using the filter designer window, wherein the first filter is within the set.

11. The non-transitory, computer-readable medium of claim 8, the stages further comprising causing second elements that do not meet the criteria of the first filter to hide or display as transparent.

12. The non-transitory, computer-readable medium of claim 8, wherein the parameter is chosen from a list of parameters populated based on element types within the GUI, wherein common attributes of the element types are used to populate the parameter list.

13. The non-transitory, computer-readable medium of claim 8, wherein the operator and operand form a comparison against an element that exists within the GUI, and wherein the criteria include an and/or condition.

14. The non-transitory, computer-readable medium of claim 8, wherein the first filter includes a color coding and transparency that are used for visually indicating the first elements.

15. A system for filtering selections in computer-aided design, comprising:
a processor that executes instructions for running a design application having an application programming interface (“API”);
a memory that includes code for a plugin, the plugin interacting with the API to cause the processor to perform stages including:
generating, with a selection engine, a filter designer window within a graphical user interface (“GUI”);
receiving criteria for a first filter to apply to an element type based on selections of a parameter, operator, and operand;
for a selected area on the GUI, determining first elements within the area that meet the element type and criteria of the first filter; and
visually indicating, on the GUI, the first elements based on the first filter.

16. The system of claim 15, wherein determining first elements within the area includes:
for a set of elements within the area criteria, automatically de-selecting elements that do not meet the criteria by making an application programming interface (“API”) call from the selection engine to the GUI.

17. The system of claim 15, the stages further comprising creating a set of different filters using the filter designer window, wherein the first filter is within the set.

18. The system of claim 15, the stages further comprising causing second elements that do not meet the criteria of the first filter to hide or display as transparent.

19. The system of claim 15, wherein the parameter is chosen from a list of parameters populated based on element types within the GUI, wherein common attributes of the element types are used to populate the parameter list.

20. The system of claim 15, wherein the first filter includes a color coding and transparency that are used for visually indicating the first elements.
